(19) United States
(12) Patent Application Publication
(10) Pub. No.: US 2024/0186474 A1
(43) Pub. Date: Jun. 6, 2024

(54) DISPLAY DEVICE

(71) Applicant: Samsung Display Co., LTD., Yongin-si (KR)

(72) Inventor: Byeong Hoon CHO, Yongin-si (KR)

(21) Appl. No.: 18/358,538

(22) Filed: Jul. 25, 2023

(30) Foreign Application Priority Data
Dec. 6, 2022 (KR) 10-2022-0168862

(51) Int. Cl. H01L 33/62; H01L 25/075

(52) U.S. Cl. CPC H01L 33/62; H01L 25/0753

(57) ABSTRACT

A display device according to one or more embodiments includes: electrodes spaced apart from each other in a pixel; a bank on the electrodes and around a light emitting area of the pixel; and light emitting elements provided between the electrodes in the light emitting area, wherein the electrodes include a first hole overlapping the bank at one side of the pixel, and a second hole overlapping the bank at another side of the pixel, and a shape of the first hole of the electrodes is different from a shape of the second hole of the electrodes.

### CROSS-REFERENCE TO RELATED APPLICATION

This application claims priority to and the benefit of Korean Patent Application No. 10-2022-0168862 filed in the Korean Intellectual Property Office on Dec. 6, 2022, the entire content of which is incorporated herein by reference.

### BACKGROUND

### 1. Field

One or more embodiments of the present disclosure relate to a display device.

### 2. Description of the Related Art

Recently, as interest in information displays is increasing, research and development of display devices are continuously conducted.

### SUMMARY

One or more embodiments of the present disclosure relate to a display device that may prevent or reduce defects due to outgas (e.g., outgassing) and may increase repair productivity.

Embodiments of the present disclosure are not limited to the embodiments mentioned above, and other technical objects that are not mentioned may be clearly understood by a person of an ordinary skill in the art using the following description.

One or more embodiments provide a display device including: electrodes spaced apart from each other in a pixel; a bank on the electrodes and around (e.g., surrounding) a light emitting area of the pixel; and light emitting elements between the electrodes in the light emitting area, wherein the electrodes include a first hole overlapping the bank at one side of the pixel, and a second hole overlapping the bank at another side of the pixel, and a shape of the first hole of the electrodes is different from a shape of the second hole of the electrodes.

The display device may further include an insulation layer between the electrodes and the light emitting elements.

The insulation layer may be between the electrodes and the bank.

The insulation layer may include a first hole overlapping the bank at the one side of the pixel, and a second hole overlapping the bank at the other side of the pixel.

The first hole of the insulation layer may overlap the first hole of the electrodes, and the second hole of the insulation layer may overlap the second hole of the electrodes.

The display device may further include a partition wall below the electrodes.

The bank may contact the partition wall through the first hole of the electrodes and the second hole of the electrodes.

The partition wall may include a recessed portion overlapping the first hole of the electrodes and the second hole of the electrodes.

The pixel may include a first pixel, a second pixel, and a third pixel, the first hole of the electrodes may be positioned between the first pixel and the second pixel, and the second hole of the electrodes may be positioned between the second pixel and the third pixel.

The electrodes may further include a third hole positioned between the third pixel and the first pixel.

The light emitting elements may include a first light emitting element, a second light emitting element, and a third light emitting element that are configured to emit light of different colors from the first pixel, the second pixel, and the third pixel, respectively.

One or more embodiments provide a display device including: electrodes spaced apart from each other in a pixel; a bank on the electrodes and around (e.g., surrounding) a light emitting area of the pixel; and light emitting elements between the electrodes in the light emitting area, wherein the bank includes first areas that extend in a first direction and are spaced apart from each other, the electrodes include a first hole and a second hole overlapping the first areas, and a shape of the first hole of the electrodes is different from a shape of the second hole of the electrodes.

The bank further may include second areas that extends in a second direction crossing the first direction and are spaced apart from each other.

The first hole of the electrodes and the second hole of the electrodes may not overlap the second area.

The electrodes may include a connection portion outside of the bank.

The pixel may include a first pixel, a second pixel, and a third pixel arranged in the second direction, and a shape of the connection portion of the electrodes of the first pixel may be different from a shape of the connection portion of the electrodes of the second pixel.

The light emitting elements may include a first light emitting element, a second light emitting element, and a third light emitting element that are configured to emit light of different colors from the first pixel, the second pixel, and the third pixel, respectively.

The first hole of the electrodes may be between the first pixel and the second pixel, and the second hole of the electrodes may be between the second pixel and the third pixel.

An area of the first hole of the electrodes may be different from an area of the second hole of the electrodes.

A number of the first holes of the electrodes may be different from a number of the second holes of the electrodes.

Particularities of other embodiments are included in the detailed description and drawings.

According to the present embodiments, by forming holes of different shapes between respective pixels, it possible to prevent or reduce defects due to outgas and simultaneously (or concurrently), to increase repair productivity by distinguishing first to third pixels.

Effects of embodiments of the present disclosure are not limited by what is illustrated herein, and more various effects are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 illustrates a perspective view of a light emitting element according to one or more embodiments.

FIG. 2 illustrates a cross-sectional view of a light emitting element according to one or more embodiments.

FIG. 3 illustrates a top plan view of a display device according to one or more embodiments.

FIG. 4 illustrates a circuit diagram of a pixel according to one or more embodiments.

FIG. 5 illustrates a top plan view of first to third pixels according to one or more embodiments.

FIG. 6 and FIG. 7 illustrate top plan views of a pixel according to one or more embodiments.

FIG. 8 illustrates a cross-sectional view taken along line A-A′ of FIG. 6.

FIG. 9 illustrates a cross-sectional view taken along line B-B′ of FIG. 6.

FIG. 10 illustrates a cross-sectional view taken along line C-C′ of FIG. 6.

FIG. 11 illustrates a cross-sectional view taken along line D-D′ of FIG. 7.

FIG. 12 illustrates a cross-sectional view taken along line E-E′ of FIG. 7.

FIG. 13 illustrates a top plan view of first to third pixels according to one or more embodiments.

FIG. 14 illustrates a top plan view of first to third pixels according to one or more embodiments.

FIG. 15 illustrates a cross-sectional view of first to third pixels according to one or more embodiments.

FIG. 16 illustrates a cross-sectional view of a pixel according to one or more embodiments.

### DETAILED DESCRIPTION

Advantages and features of the present disclosure and methods of accomplishing the same may be understood more readily by reference to the following detailed description of embodiments and the accompanying drawings. The present disclosure may, however, be embodied in different forms and should not be construed as limited to the embodiments set forth herein. The present embodiments are provided so that this disclosure will be thorough and complete, and will fully convey the scope of the present disclosure to those skilled in the art, and further, the present disclosure is only defined by scopes of claims.

The terms used herein are for the purpose of describing particular embodiments only and are not intended to be limiting. As used herein, the singular forms “a”, “an” and “the” are intended to include the plural forms as well, unless the context clearly indicates otherwise. It will be further understood that the terms “comprise” and/or “comprising”, “include” or “including”, and “have” or “having”, when used in the present disclosure, specify the presence of stated elements, steps, operations, and/or devices, but do not preclude the presence or addition of one or more other elements, steps, operations, and/or devices.

The term “connection” or “coupling” may comprehensively mean a physical and/or electrical connection or coupling. This may comprehensively mean a direct or indirect connection or coupling, and an integrated or non-integrated connection or coupling.

It will be understood that when an element or a layer is referred to as being “on” another element or layer, it can be directly on another element or layer (e.g., without any intervening elements therebetween), or one or more intervening elements or layers may also be present. Throughout the specification, the same reference numerals denote the same constituent elements.

Although the terms “first”, “second”, and the like are used to describe various constituent elements, these constituent elements are not limited by these terms. These terms are used only to distinguish one constituent element from another constituent element. Therefore, the first constituent elements described below may be the second constituent elements within the technical spirit of the present disclosure.

As used herein, the terms “use,” “using,” and “used” may be considered synonymous with the terms “utilize,” “utilizing,” and “utilized,” respectively.

As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

As used herein, the term “and/or” includes any and all combinations of one or more of the associated listed items.

Further, the use of “may” when describing embodiments of the present disclosure refers to “one or more embodiments of the present disclosure”.

Spatially relative terms, such as “beneath,” “below,” “lower,” “above,” “upper,” “bottom,” “top” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

As used herein, the terms “substantially”, “about”, and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Hereinafter, embodiments of the present disclosure will be described in more detail with reference to the accompanying drawings.

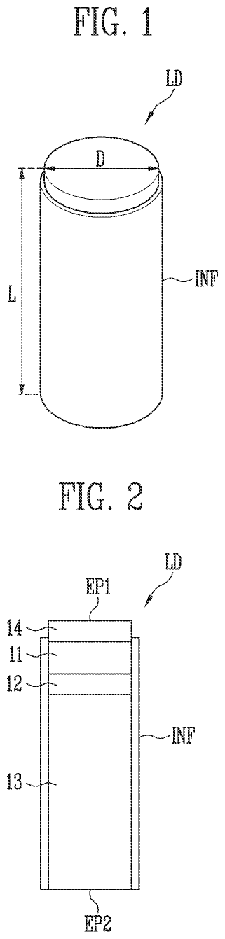

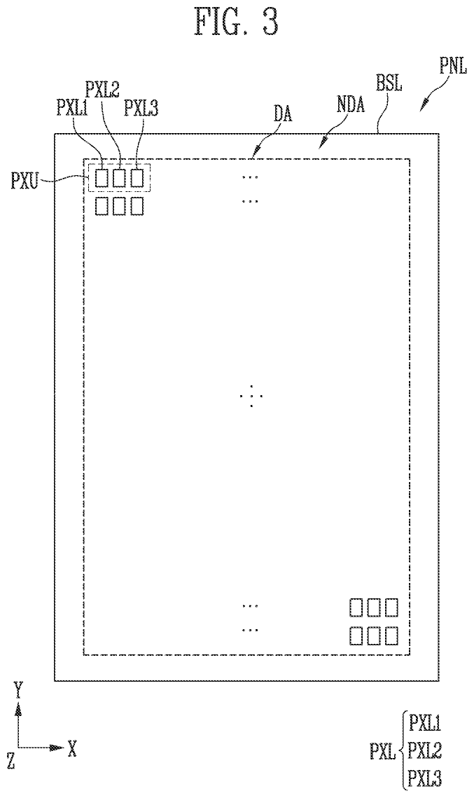

FIG. 1 illustrates a perspective view of a light emitting element according to one or more embodiments. FIG. 2 illustrates a cross-sectional view of a light emitting element according to one or more embodiments. FIG. 1 and FIG. 2 illustrate a cylindrically shaped light emitting element LD, but a type (or kind) and/or shape of the light emitting element LD is not limited thereto.

Referring to FIG. 1 and FIG. 2, a light emitting element LD may include a first semiconductor layer 11, an active layer 12, a second semiconductor layer 13, and/or an electrode layer 14.

The light emitting element LD may be formed to have a cylindrical shape extending along one direction. The light emitting element LD may have a first end portion EP1 and a second end portion EP2. One selected from among the first and second semiconductor layers 11 and 13 may be provided on (or at) the first end portion EP1 of the light emitting element LD. The remaining one selected from among the first and second semiconductor layers 11 and 13 may be provided on (or at) the second end portion EP2 of the light emitting element LD. For example, the first semiconductor layer 11 may be provided on the first end portion EP1 of the light emitting element LD, and the second semiconductor layer 13 may be provided on the second end EP2 of the light emitting element LD.

In some embodiments, the light emitting element LD may be a light emitting element manufactured in a cylindrical shape through an etching method or the like. In the present specification, the “cylindrical shape” includes a rod-like shape and/or bar-like shape with an aspect ratio greater than 1, such as a circular cylinder and/or a polygonal cylinder, but a shape of a cross-section thereof is not limited.

The light emitting element LD may have a size as small as a nanometer scale to a micrometer scale. For example, the light emitting element LD may each have a diameter D (or width) and/or a length L ranging from a nanometer scale to a micrometer scale. However, the size of the light emitting element LD is not limited thereto, and the size of the light emitting element LD may be variously suitably changed according to design conditions of the devices using a light emitting device using the light emitting element LD as a light source, for example, a display device.

The first semiconductor layer 11 may be a first conductive semiconductor layer. For example, the first semiconductor layer 11 may include a p-type semiconductor layer. For example, the first semiconductor layer 11 may include at least one semiconductor material selected from among InAlGaN, GaN, AlGaN, InGaN, and AlN, and may include a p-type semiconductor layer doped with a first conductive dopant such as Mg. However, the material included in the first semiconductor layer 11 is not limited thereto, and the first semiconductor layer 11 may be made of one or more suitable materials.

The active layer 12 may be provided between the first semiconductor layer 11 and the second semiconductor layer 13. The active layer 12 may include one selected from among a single well structure, a multi-well structure, a single quantum well structure, a multi-quantum well (MQW) structure, a quantum dot structure, and a quantum line structure, but is not necessarily limited thereto. The active layer 12 may include GaN, InGaN, InAlGaN, AlGaN, and/or AlN, and in addition, it may include one or more other suitable materials.

When a voltage of a threshold voltage or more is applied to respective ends of the light emitting element LD, the light emitting element LD emits light while electron-hole pairs are combined in the active layer 12. By controlling the light emitting of the light emitting element LD by using this principle, the light emitting element LD may be used as a light source for various suitable light emitting devices in addition to pixels of a display device.

The second semiconductor layer 13 is provided on the active layer 12, and may include a semiconductor layer of a type (a doping type or kind) different from that of the first semiconductor layer 11. The second semiconductor layer 13 may include an n-type semiconductor layer. For example, the second semiconductor layer 13 may include a semiconductor material of one selected from among InAlGaN, GaN, AlGaN, InGaN, and AlN, and may include an n-type semiconductor layer doped with a second conductive dopant such as Si, Ge, Sn, and/or the like. However, the material included in the second semiconductor layer 13 is not limited thereto, and the second semiconductor layer 13 may be made of one or more suitable materials.

The electrode layer 14 may be provided on the first end portion EP1 and/or the second end portion EP2 of the light emitting element LD. FIG. 2 illustrates the case in which the electrode layer 14 is formed on the first semiconductor layer 11, but the present disclosure is not necessarily limited thereto. For example, a separate electrode layer may be further provided on the second semiconductor layer 13.

The electrode layer 14 may include a transparent metal and/or transparent metal oxide. As an example, the electrode layer 14 may include at least one selected from among an indium tin oxide (ITO), an indium zinc oxide (IZO), and a zinc tin oxide (ZTO), but is not limited thereto. As such, when the electrode layer 14 is made of the transparent metal and/or transparent metal oxide, light generated in the active layer 12 of the light emitting element LD may transmit through the electrode layer 14 to be emitted to the outside of the light emitting element LD.

An insulation film INF may be provided on a surface of the light emitting element LD. The insulation film INF may be directly provided on surfaces of the first semiconductor layer 11, the active layer 12, the second semiconductor layer 13, and/or the electrode layer 14. The insulation film INF may expose the first and second end portions EP1 and EP2 of the light emitting element LD having different polarities. In some embodiments, the insulation film INF may expose side portions of the electrode layer 14 and/or the second semiconductor layer 13 that are adjacent to the first and second end portions EP1 and EP2 of the light emitting element LD.

The insulation film INF may prevent or reduce the risk of an electrical short circuit that may occur when the active layer 12 contacts conductive materials other than the first and second semiconductor layers 11 and 13. The insulation film INF may minimize or reduce surface defects of the light emitting elements LD to improve lifespan and luminous efficiency of the light emitting elements LD.

The insulation film INF may include at least one selected from among a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), and a titanium oxide (TiOx). For example, the insulation film INF may be configured as a double layer, and respective layers configuring the double layer may include different materials. For example, the insulation film INF may be formed as a double layer made of an aluminum oxide (AlOx) and a silicon oxide (SiOx), but is not limited thereto. In some embodiments, the insulation film INF may not be provided (e.g., may be omitted).

A light emitting device including the light emitting element LD described above may be used in various types (or kinds) of suitable devices that require (or desire) a light source in addition to a display device. For example, the light emitting elements LD may be provided in each pixel of a display panel, and the light emitting elements LD may be used as a light source of each pixel. However, an application field of the light emitting element LD is not limited to the above-described example. For example, the light emitting element LD may be used in other types (or kinds) of devices that require (or desire) a light source, such as a lighting device.

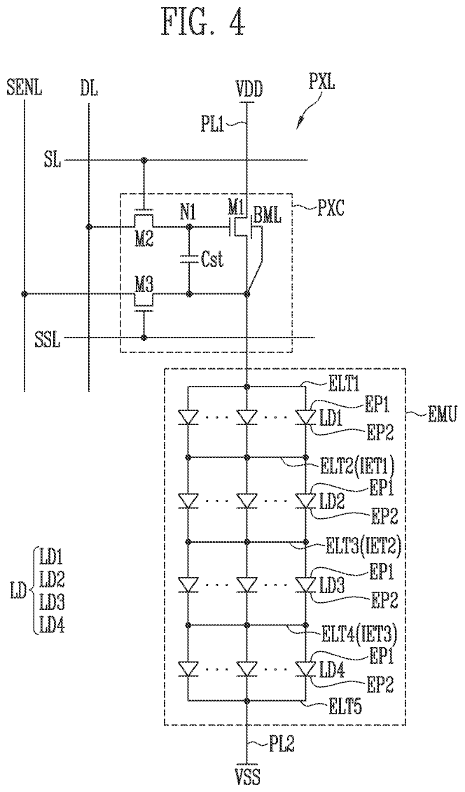

FIG. 3 illustrates a top plan view of a display device according to one or more embodiments.

FIG. 3 illustrates a display device, in particular, a display panel PNL provided in the display device as an example of an electronic device that may use the light emitting element LD described in the embodiments of FIG. 1 and FIG. 2 as a light source.

For better understanding and ease of description, FIG. 3 briefly illustrates a structure of the display panel PNL based on a display area DA. However, in some embodiments, at least one driving circuit portion (for example, at least one selected from among a scan driver and a data driver), wires, and/or pads may be further provided in the display panel PNL.

Referring to FIG. 3, the display panel PNL and a base layer BSL for forming the display panel include the display area DA for displaying an image and a non-display area NDA excluding the display area DA. The display area DA may configure a screen on which an image is displayed, and the non-display area NDA may be the remaining area except for the display area DA.

A pixel unit PXU may be provided in the display area DA. The pixel unit PXU may include a first pixel PXL1, a second pixel PXL2, and/or a third pixel PXL3. Hereinafter, when arbitrarily referring to at least one selected from among the first pixel PXL1, the second pixel PXL2, and the third pixel PXL3, or when comprehensively referring to two or more types (or kinds) of pixels thereof, they will be referred to as a “pixel PXL” or “pixels PXL”.

The pixels PXL may be regularly arranged according to a stripe or PENTILE® arrangement structure (PENTILE® is a registered trademark owned by Samsung Display Co., Ltd.). However, the arrangement structure of the pixels PXL is not limited thereto, and the pixels PXL may be arranged in the display area DA in one or more suitable structures and/or methods.

In some embodiments, two or more types (or kinds) of pixels PXL emitting light of different colors may be provided in the display area DA. For example, in the display area DA, the first pixels PXL1 for emitting light of the first color, the second pixels PXL2 for emitting light of the second color, and the third pixels PXL3 for emitting light of the third color may be arranged. At least one selected from among first to third pixels PXL1, PXL2, and PXL3 provided to be adjacent to each other may form one pixel unit PXU that may emit light of one or more colors. For example, each of the first to third pixels PXL1, PXL2, and PXL3 may be a pixel that emits light of a set or predetermined color. In some embodiments, the first pixel PXL1 may be a red pixel that emits (or is configured to emit) red light, the second pixel PXL2 may be a green pixel that emits (or is configured to emit) green light, and the third pixel PXL3 may be a blue pixel that emits (or is configured to emit) blue light, but the present disclosure is not limited thereto.

In the embodiment, the first pixel PXL1, the second pixel PXL2, and the third pixel PXL3 are provided with light emitting elements of the same color, and include color conversion layers and/or color filter layers of different colors provided on respective light emitting elements, so that they may emit light of the first color, the second color, and the third color, respectively. In some embodiments, the first pixel PXL1, the second pixel PXL2, and the third pixel PXL3 are each provided with a first color light emitting element, a second color light emitting element, and a third color light emitting element as a light source, respectively, so that they respectively emit light of the first color, second color, and third color. However, the color, type (or kind), and/or number of pixels PXL configuring each pixel unit PXU are not particularly limited. For example, the color of light emitted by each pixel PXL may be variously suitably changed.

The pixel PXL may include at least one light source driven by a set or predetermined control signal (for example, a scan signal and a data signal) and/or a set or predetermined power source (for example, a first power source and a second power source). In the embodiments, the light source may include at least one light emitting device LD according to one of the embodiments of FIG. 1 and FIG. 2, for example, ultra-small cylindrical shape light emitting elements LD having a size as small as nanometer scale to micrometer scale. However, the present disclosure is not limited thereto, and one or more suitable types (or kinds) of light emitting elements LD may be used as a light source of the pixel PXL.

In the embodiments, each pixel PXL may be configured as active pixel. However, the type (or kind), structure, and/or driving method of pixels PXL that may be applied to the display device are not particularly limited. For example, each pixel PXL may be configured as a pixel of a passive or active light emitting display device of one or more suitable structures and/or driving methods.

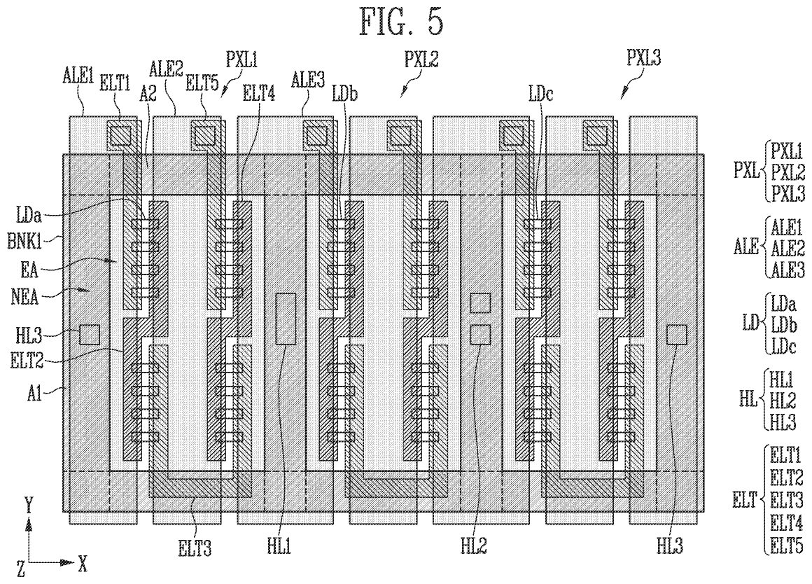

FIG. 4 illustrates a circuit diagram of a pixel according to one or more embodiments.

The pixel PXL shown in FIG. 4 may be one selected from among the first pixel PXL1, the second pixel PXL2, and the third pixel PXL3 provided in the display panel PNL of FIG. 3. The first pixel PXL1, the second pixel PXL2, and the third pixel PXL3 may have substantially the same or similar structure.

Referring to FIG. 4, the pixel PXL may further include a light emitting part EMU for generating light at luminance corresponding to a data signal, and a pixel circuit PXC for driving a light emitting part EMU.

The pixel circuit PXC may be connected between a first power source VDD and the light emitting part EMU. The pixel circuit PXC may be connected to a scan line SL and a data line DL of the pixel PXL to control an operation of the light emitting part EMU in response to a scan signal and a data signal supplied from the scan line SL and the data line DL. The pixel circuit PXC may be further selectively connected to a sensing signal line SSL and a sensing line SENL.

The pixel circuit PXC may include at least one transistor and a capacitor. For example, the pixel circuit PXC may include a first transistor M1, a second transistor M2, a third transistor M3, and a storage capacitor Cst.

The first transistor M1 may be connected between the first power source VDD and a first connection electrode ELT1. A gate electrode of the first transistor M1 may be connected to a first node N1. The first transistor M1 may control a driving current supplied to the light emitting part EMU in response to a voltage of the first node N1. For example, the first transistor M1 may be a driving transistor that controls a driving current of the pixel PXL.

In the embodiments, the first transistor M1 may optionally include a lower conductive layer BML (also referred to as a “lower electrode”, “back gate electrode”, or “lower light blocking layer”). The gate electrode of the first transistor M1 and the lower conductive layer BML may overlap each other with an insulation layer interposed therebetween. In the embodiments, the lower conductive layer BML may be connected to one electrode of the first transistor M1, for example a source or drain electrode thereof.

When the first transistor M1 includes the lower conductive layer BML, by applying a back-biasing voltage to the lower conductive layer BML of the first transistor M1 when the pixel PXL is driven, a back-biasing technique (or a sync technique) of moving a threshold voltage of the first transistor M1 in a negative or positive direction may be applied. For example, by connecting the lower conductive layer BML to the source electrode of the first transistor M1 to apply a source-sync technique, the threshold voltage of the first transistor M1 may be moved in the negative or positive direction. When the lower conductive layer BML is provided under a semiconductor pattern forming a channel of the first transistor M1, the lower conductive layer BML may serve as a light blocking pattern to stabilize (e.g., improve) an operating characteristic of the first transistor M1. However, the function and/or utilization method of the lower conductive layer BML is not limited thereto.

The second transistor M2 may be connected between the data line DL and the first node N1. A gate electrode of the second transistor M2 may be connected to the scan line SL. When a scan signal of a gate-on voltage (for example, a high level voltage) is supplied from the scan line SL, the second transistor M2 may be turned on to connect the data line DL and the first node N1.

For each frame period, a data signal of the corresponding frame is supplied to the data line DL, and the data signal be transmitted to the first node N1 through the turned-on second transistor M2 during a period in which the scan signal of the gate-on voltage is supplied. For example, the second transistor M2 may be a switching transistor for transmitting each data signal to the inside of the pixel PXL.

One electrode of the storage capacitor Cst may be connected to the first node N1, and the other electrode thereof may be connected to a second electrode of the first transistor M1. The storage capacitor Cst may be charged with a voltage corresponding to the data signal supplied to the first node N1 during each frame period.

The third transistor M3 may be connected between the first connection electrode ELT1 (or the second electrode of the first transistor M1) and the sensing line SENL. A gate electrode of the third transistor M3 may be connected to a sensing signal line SSL. The third transistor M3 may transmit a voltage applied to the first connection electrode ELT1 to the sensing line SENL according to a sensing signal supplied to the sensing signal line SSL. The voltage transmitted through the sensing line SENL may be provided to an external circuit (for example, a timing controller), and the external circuit may detect characteristic information (for example, a threshold voltage of the first transistor M1) of each pixel PXL based on the supplied voltage. The detected characteristic information may be used to convert image data so that a characteristic deviation between the pixels PXL is compensated.

In FIG. 4, all the transistors included in the pixel circuit PXC are illustrated as n-type transistors, but the present disclosure is not limited thereto. For example, at least one selected from among the first, second, and third transistors M1, M2, and M3 may be changed to a p-type transistor.

The structure and driving method of the pixel PXL may be variously suitably changed. For example, the pixel circuit PXC may be configured as a pixel circuit having one or more suitable structures and/or driving methods in addition to that of the embodiment shown in FIG. 4.

For example, the pixel circuit PXC may not include the third transistor M3. The pixel circuit PXC may further include other circuit elements such as a compensation transistor for compensating for a threshold voltage of the first transistor M1, an initialization transistor for initializing the voltage of the first node N1 and/or of the first connection electrode ELT1, a light emitting control transistor for controlling a period in which a driving current is supplied to the light emitting unit EMU, and/or a boosting capacitor for boosting the voltage of the first node N1.

The light emitting part EMU may include at least one light emitting element LD connected between the first power source VDD and a second power source VSS, for example, a plurality of light emitting elements LD.

For example, the light emitting part EMU may include the first connection electrode ELT1 connected to the first power source VDD through the pixel circuit PXC and a first power line PL1, a fifth connection electrode ELT5 connected to the second power source VSS through a second power line PL2, and a plurality of light emitting elements LD connected between the first and fifth connection electrodes ELT1 and ELT5.

The first and second power sources VDD and VSS may have different potentials so that the light emitting elements LD may emit light. For example, the first power source VDD may be set as a high potential power source, and the second power source VSS may be set as a low potential power source.

In the embodiments, the light emitting part EMU may include at least one serial stage. Each serial stage may include a pair of electrodes (for example, two electrodes) and at least one light emitting element LD connected in a forward direction between the pair of electrodes. Here, the number of serial stages forming the light emitting part EMU and the number of light emitting elements LD forming each serial stage are not particularly limited. For example, the number of the light emitting elements LD configuring respective serial stages may be the same or different from each other, but the number of the light emitting elements LD is not particularly limited.

For example, the light emitting part EMU may include a first serial stage including at least one first light emitting element LD1, a second serial stage including at least one second light emitting element LD2, a third serial stage including at least one third light emitting element LD3, and a fourth serial stage including at least one fourth light emitting element LD4.

The first serial stage may include the first connection electrode ELT1, the second connection electrode ELT2, and at least one first light emitting element LD1 connected between the first and second connection electrodes ELT1 and ELT2. Each first light emitting element LD1 may be connected in a forward direction between the first and second connection electrodes ELT1 and ELT2. For example, the first end portion EP1 of the first light emitting element LD1 may be connected to the first connection electrode ELT1, and the second end portion EP2 of the first light emitting element LD1 may be connected to the second connection electrode ELT2.

The second serial stage may include the second connection electrode ELT2, a third connection electrode ELT3, and at least one second light emitting element LD2 connected between the second and third connection electrodes ELT2 and ELT3. Each second light emitting element LD2 may be connected in a forward direction between the second and third connection electrodes ELT2 and ELT3. For example, the first end portion EP1 of the second light emitting element LD2 may be connected to the second connection electrode ELT2, and the second end portion EP2 of the second light emitting element LD2 may be connected to third connection electrode ELT3.

The third serial stage may include the third connection electrode ELT3, the fourth connection electrode ELT4, and at least one third light emitting element LD3 connected between the third and fourth connection electrodes ELT3 and ELT4. Each third light emitting element LD3 may be connected in a forward direction between the third and fourth connection electrodes ELT3 and ELT4. For example, the first end portion EP1 of the third light emitting element LD3 may be connected to the third connection electrode ELT3, and the second end portion EP2 of the third light emitting element LD3 may be connected to fourth connection electrode ELT4.

The fourth serial stage may include the fourth connection electrode ELT4, the fifth connection electrode ELT5, and at least one fourth light emitting element LD4 connected between the fourth and fifth connection electrodes ELT4 and ELT5. Each fourth light emitting element LD4 may be connected in a forward direction between the fourth and fifth connection electrodes ELT4 and ELT5. For example, the first end portion EP1 of the fourth light emitting element LD4 may be connected to the fourth connection electrode ELT4, and the second end portion EP2 of the fourth light emitting element LD4 may be connected to the fifth connection electrode ELT5.

A first electrode of the light emitting part EMU, for example, the first connection electrode ELT1 may be an anode electrode of the light emitting part EMU. A last electrode of the light emitting part EMU, for example, the fifth connection electrode ELT5 may be a cathode electrode of the light emitting part EMU.

The remaining electrodes of the light emitting part EMU, for example, the second connection electrode ELT2, the third connection electrode ELT3, and/or the fourth connection electrode ELT4, may configure respective intermediate electrodes. For example, the second connection electrode ELT2 may configure a first intermediate electrode IET1, the third connection electrode ELT3 may configure a second intermediate electrode IET2, and the fourth connection electrode ELT4 may configure a third intermediate electrode IET3.

When the light emitting elements LD are connected in a serial/parallel structure, power efficiency may be improved compared with when the same number of light emitting elements LD are connected only in parallel. In the pixel PXL in which the light emitting elements LD are connected in a serial/parallel structure, even if a short circuit defect occurs at some of the serial stages, because a set or predetermined luminance may be displayed through the light emitting elements LD in the remaining serial stages, the possibility of dark spot defects of the pixel PXL may be reduced. However, the present disclosure is not limited thereto, and the light emitting part EMU may be configured by connecting the light emitting elements LD only in series or only in parallel.

Each of the light emitting elements LD may include at least one electrode (for example, the first connection electrode ELT1), the first end portion EP1 (for example, a p-type end portion) connected to the first power source VDD via the pixel circuit PXC and/or the first power line PL1, and the second end portion EP2 (for example, an p-type end portion) connected to the second power source VSS via at least one other electrode (for example, the fifth connection electrode ELT5) and the second power line PL2. For example, the light emitting elements LD may be connected in a forward direction between the first power source VDD and the second power source VSS. The light emitting elements LD connected to the forward direction may configure the effective or suitable light sources of the light emitting part EMU.

When a driving current is supplied through the corresponding pixel circuit PXC, the light emitting elements LD may emit light with luminance corresponding to the driving current. For example, during each frame period, the pixel circuit PXC may supply a driving current corresponding to a gray value to be displayed in the corresponding frame to the light emitting part EMU. Accordingly, while the light emitting elements LD emit light with luminance corresponding to the driving current, the light emitting part EMU may display the luminance corresponding to the driving current.

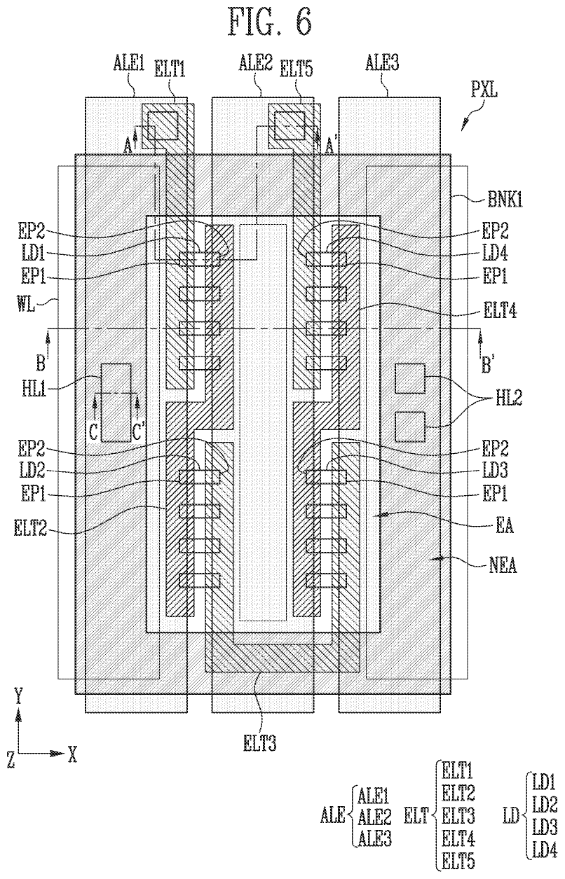

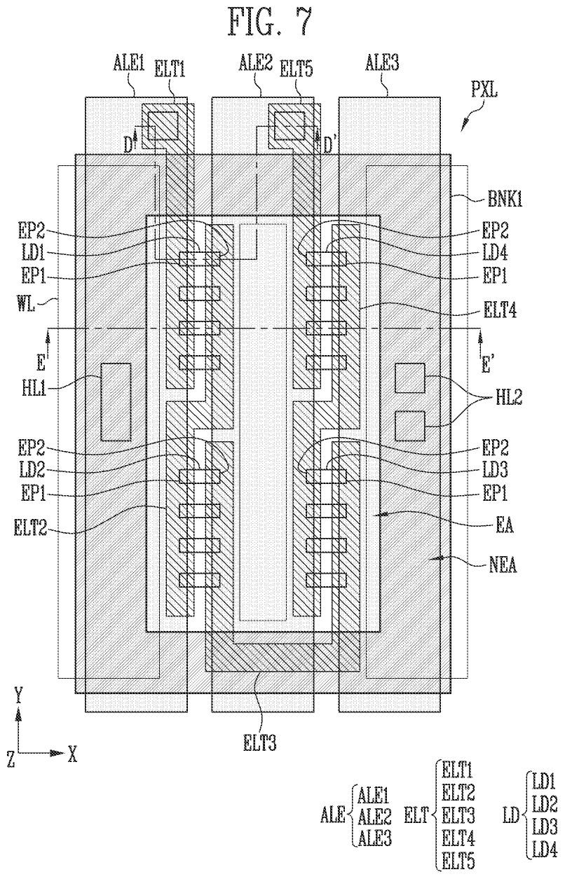

FIG. 5 illustrates a top plan view of first to third pixels according to one or more embodiments. In FIG. 5, some components of the pixel PXL are omitted (are not included) for better understanding and ease of description. FIG. 6 and FIG. 7 illustrate top plan views of a pixel according to one or more embodiments. As an example, FIG. 6 and FIG. 7 may illustrate one selected from among the first to third pixels PXL1, PXL2, and PXL3 configuring the pixel unit PXU of FIG. 5, and the first to third pixels PXL1, PXL2, and PXL3 may be substantially the same or similar to each other. FIG. 5 to FIG. 7 illustrate the embodiments in which each pixel PXL includes the light emitting elements LD provided in the four serial stages as shown in FIG. 4, but the number of serial stages of each pixel PXL may be variously suitably changed according to embodiments.

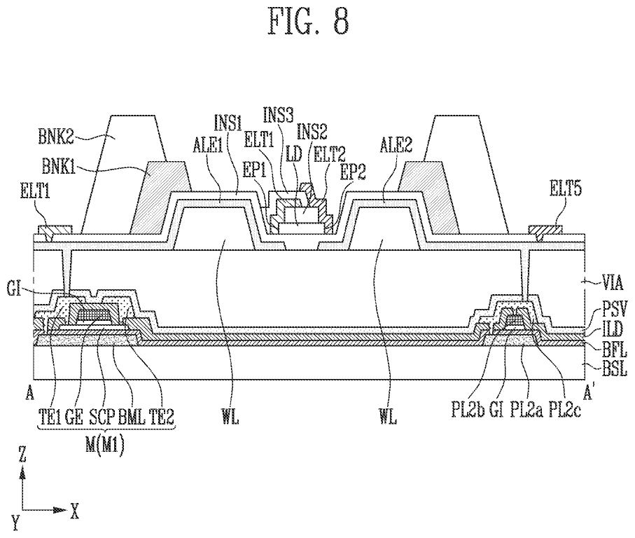

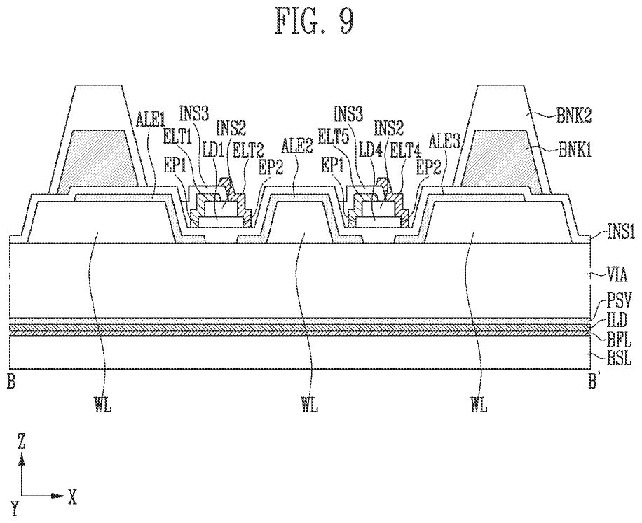

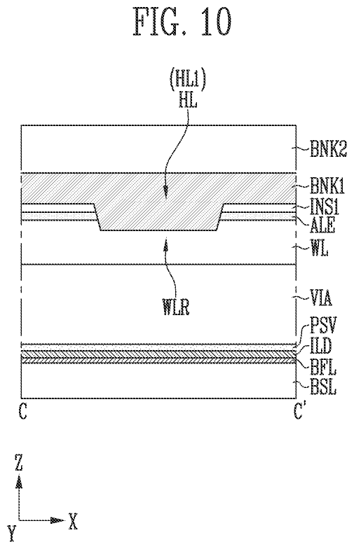

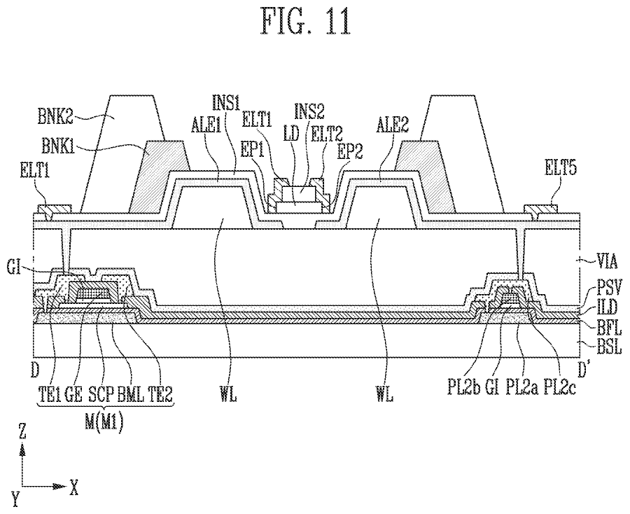

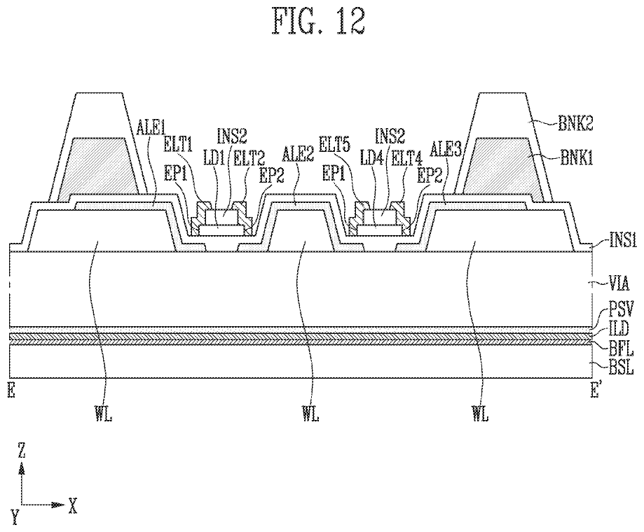

FIG. 8 illustrates a cross-sectional view taken along line A-A′ of FIG. 6. FIG. 9 illustrates a cross-sectional view taken along line B-B′ of FIG. 6. FIG. 10 illustrates a cross-sectional view taken along line C-C′ of FIG. 6. FIG. 11 illustrates a cross-sectional view taken along line D-D′ of FIG. 7. FIG. 12 illustrates a cross-sectional view taken along line E-E′ of FIG. 7.

Hereinafter, when arbitrarily referring to one or more light emitting element among first to fourth light emitting elements LD1, LD2, LD3, and LD4, or comprehensively referring to two or more light emitting elements, it or they will be referred to as a “light emitting element LD” or “light emitting elements LD”. When arbitrarily referring to at least one selected from among electrodes including first to third electrodes ALE1, ALE2, and ALE3, it or they will be referred to as an “electrode ALE” or “electrodes ALE”, and when arbitrarily referring to at least one selected from among electrodes including first to fifth connection electrodes ELT1, ELT2, ELT3, ELT4, and ELT5, it or they will be referred to as a “connection electrode ELT” or “connection electrodes ELT”.

Referring to FIG. 5 to FIG. 7, each pixel PXL may include the light emitting area EA and the non-light emitting area NEA. The light emitting area EA may be an area that may emit light by including the light emitting elements LD. The non-light emitting area NEA may be provided to surround the light emitting area EA. The non-light emitting area NEA may be an area in which a first bank BNK1 surrounding the light emitting area EA is provided. The first bank BNK1 may be provided to the non-light emitting area NEA to be provided so as to at least partially surround the light emitting area EA.

The first bank BNK1 may include an opening overlapping the light emitting area EA. The opening of the first bank BNK1 may provide a space in which the light emitting elements LD may be provided in a step of supplying the light emitting elements LD to each of the pixels PXL. For example, a desired type (or kind) and/or amount of light emitting element ink may be supplied to a space partitioned by the opening of the first bank BNK1.

The first bank BNK1 may include an organic material such as an acrylate resin, an epoxy resin, a phenolic resin, a polyamide resin, a polyimide resin, a polyester resin, a polyphenylenesulfide resin, and/or a benzocyclobutene (BCB). However, it is not necessarily limited thereto, and the first bank BNK1 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), and/or a titanium oxide (TiOx), and one or more suitable types (or kinds) of inorganic materials.

In some embodiments, the first bank BNK1 may include at least one light blocking and/or reflective material. Accordingly, light leakage between adjacent pixels PXL may be prevented or reduced. For example, the first bank BNK1 may include at least one black pigment.

Each pixel PXL may include partition walls WL, electrodes ALE, light emitting elements LD, and/or connection electrodes ELT.

The partition walls WL may overlap the light emitting area EA, and may be spaced apart from each other. The partition walls WL may be at least partially provided in the non-light emitting area NEA. The partition walls WL may extend along the second direction (Y-axis direction), and may be spaced apart from each other along the first direction (X-axis direction).

The partition walls WL may at least partially overlap at least one electrode ALE in the light emitting area EA. For example, the partition walls WL may be provided below the electrodes ALE, respectively. As the partition walls WL are provided under one area of each of the electrodes ALE, one area of each of the electrodes ALE in areas in which the partition walls WL are formed may protrude in an upper direction of the pixel PXL, for example, a third direction (Z-axis direction). When the partition walls WL and/or the electrodes ALE include a reflective material, a reflective wall structure may be formed around the light emitting elements LD. Accordingly, as light emitted from the light emitting elements LD may be directed in an upper direction (for example, a front direction of the display panel PNL including a set or predetermined viewing angle range) of the pixel PXL, light emitting efficiency of the pixel PXL may be improved.

The electrodes ALE may be provided in at least light emitting area EA. The electrodes ALE may extend along a second direction (Y-axis direction), and may be spaced apart from each other along a first direction (X-axis direction).

The first to third electrodes ALE1, ALE2, and ALE3 may extend along the second direction (Y-axis direction), respectively, and may be spaced apart from each other along the first direction (X-axis direction) to be sequentially provided. Some of the electrodes ALE may be connected to the pixel circuit (PXC of FIG. 4) and/or a set or predetermined power line through a contact hole. For example, the first electrode ALE1 may be connected to the pixel circuit PXC and/or the first power line PL1 through the contact hole, and the second electrode ALE2 may be connected to the second power line PL2 through the contact hole.

In some embodiments, some of the electrodes ALE may be electrically connected to some of the connection electrodes ELT through a contact hole. For example, the first electrode ALE1 may be electrically connected to the first connection electrode ELT1 through the contact hole, and the second electrode ALE2 may be electrically connected to the fifth connection electrode ELT5 through the contact hole.

A pair of electrodes ALE adjacent to each other may receive different signals in an alignment step of the light emitting elements LD. For example, when the first to third electrodes ALE1, ALE2, and ALE3 are sequentially arranged along the first direction (X-axis direction), the first electrode ALE1 and the second electrode ALE2 may be supplied with different alignment signals, and the second electrode ALE2 and the third electrode ALE3 may be supplied with different alignment signals.

In the embodiments, a hole HL may be formed in the electrodes ALE and a first insulation layer (INS1 in FIG. 10). Even if outgas is generated from a via layer VIA and/or the partition wall WL made of an organic material during the manufacturing process of the display device, because the outgas is released to the outside through the hole HL formed in the electrodes ALE and the first insulation layer INS1, defects due to the outgas may be minimized or reduced.

The hole HL may be provided in the non-light emitting area NEA. For example, the hole HL may be provided to overlap the first bank BNK1. For example, when the first bank BNK1 includes a first area A1 extending along the second direction (Y-axis direction) and a second area A2 extending along the first direction (X-axis direction), the hole HL may overlap the first area A1. The hole HL may not overlap the second area A2. In the embodiments, the second area A2 may be an area in which the connection electrode ELT and/or the like are provided. Accordingly, even if a step is partially formed by forming the hole HL in the first area A1, the connection electrode ELT formed in the second area A2 may not be affected (or substantially affected). However, the present disclosure is not necessarily limited thereto, and the hole HL may be provided in one or more suitable positions and/or shapes around the light emitting area EA.

The hole HL may include first to third holes HL1, HL2, and HL3 positioned between respective pixels PXL. The first hole HL1 may be positioned between the first pixel PXL1 and the second pixel PXL2, the second hole HL2 may be positioned between the second pixel PXL2 and the third pixel PXL3, and the third hole HL3 may be positioned between the third pixel PXL3 and the first pixel PXL1. The first hole HL1 may overlap the first bank BNK1 at one side of the second pixel PXL2 (or the other side of the first pixel PXL1), the second hole HL2 may overlap the first bank BNK1 at the other side of the second pixel PXL2 (or one side of the third pixel PXL3), and the third hole HL3 may overlap the first bank BNK1 at the other side of the third pixel PXL3 (or one side of the first pixel PXL1).

The first to third holes HL1, HL2, and HL3 may be formed in different shapes. For example, the first to third holes HL1, HL2, and HL3 may be formed in different areas. Different numbers of first to third holes HL1, HL2, and HL3 may be formed. In this way, the first to third pixels PXL1, PXL2, and PXL3 are differentiated by forming the shape, area, and/or number of the hole HL differently between the pixels PXL, so that productivity may be increased by repair-printing the light emitting elements LD for each PXL. In addition, by using the hole HL to distinguish the electrodes ALE receiving different alignment signals, it is possible to easily check whether the light emitting elements LD are deflectively aligned.

FIG. 5 illustrates the case in which the first hole HL1 is formed to have one rectangular shape, the second hole HL2 is formed to have two square shapes, and the third hole HL3 is formed to have one square shape, but the present disclosure is not necessarily limited thereto.

Each of the light emitting elements LD may be aligned between a pair of electrodes ALE in the light emitting area EA. Each of the light emitting elements LD may be electrically connected between a pair of connection electrodes ELT. The first to third pixels PXL1, PXL2, and PXL3 may include first or third color light emitting elements LDa, LDb, and LDc emitting (e.g., configured to emit) light of different colors, respectively. The first to third color light emitting elements LDa, LDb, and LDc may be configured of first to fourth light emitting elements LD1, LD2, LD3, and LD4, respectively.

The first light emitting element LD1 may be aligned between the first and second electrodes ALE1 and ALE2. The first light emitting element LD1 may be electrically connected between the first and second electrodes ELT1 and ELT2. As an example, the first light emitting element LD1 may be aligned in an first area (for example, an upper end area) of the first and second electrodes ALE1 and ALE2, and the first end portion EP1 of the first light emitting element LD1 may electrically connected to the first connection electrode ELT1, and the second end portion EP2 of the first light emitting element LD1 may be electrically connected to the second connection electrode ELT2.

The second light emitting element LD2 may be aligned between the first and second electrodes ALE1 and ALE2. The second light emitting element LD2 may be electrically connected between the second and third connection electrodes ELT2 and ELT3. As an example, the second light emitting element LD2 may be aligned in a second area (for example, a lower end area) of the first and second electrodes ALE1 and ALE2, and the first end portion EP1 of the second light emitting element LD2 may electrically connected to the second connection electrode ELT2, and the second end portion EP2 of the second light emitting element LD2 may be electrically connected to the third connection electrode ELT3.

The third light emitting element LD3 may be aligned between the second and third electrodes ALE2 and ALE3. The third light emitting element LD3 may be electrically connected between the third and fourth connection electrodes ELT3 and ELT4. As an example, the third light emitting element LD3 may be aligned in a second area (for example, a lower end area) of the second and third electrodes ALE2 and ALE3, and the first end portion EP1 of the third light emitting element LD3 may electrically connected to the third connection electrode ELT3, and the second end portion EP2 of the third light emitting element LD3 may be electrically connected to the fourth connection electrode ELT4.

The fourth light emitting element LD4 may be aligned between the second and third electrodes ALE2 and ALE3. The fourth light emitting element LD4 may be electrically connected between the fourth and fifth connection electrodes ELT4 and ELT5. As an example, the fourth light emitting element LD4 may be aligned in the first area (for example, the upper end area) of the second and third electrodes ALE2 and ALE3, and the first end portion EP1 of the fourth light emitting element LD4 may electrically connected to the fourth connection electrode ELT4, and the second end portion EP2 of the fourth light emitting element LD4 may be electrically connected to the fifth connection electrode ELT5.

For example, the first light emitting element LD1 may be provided in an upper left area of the light emitting area EA, and the second light emitting element LD2 may be provided in a lower left area of the light emitting area EA. The third light emitting element LD3 may be provided in a lower right area of the light emitting area EA, and the fourth light emitting element LD4 may be provided in an upper right area of the light emitting area EA. However, the arrangement and/or connection structure of the light emitting elements LD may be variously suitably changed depending on the structure of the light emitting part EMU and/or the number of serial stages.

Each of the connection electrodes ELT may be at least provided in the light emitting area EA, and may be provided to overlap at least one electrode ALE and/or at least one light emitting element LD. For example, each of the connection electrodes ELT may be formed on the electrodes ALE and/or the light emitting elements LD so as to overlap the electrodes ALE and/or the light emitting elements LD to be electrically connected to the light emitting elements LD.

The first connection electrode ELT1 may be provided on the first area (for example, the upper area) of the first electrode ALE1 and the first end portions EP1 of the first light emitting elements LD1 to be electrically connected to the first end portions EP1 of the first light emitting elements LD1.

The second connection electrode ELT2 may be provided on the first area (for example, the upper end area) of the second electrode ALE2 and the second end portions EP2 of the first light emitting elements LD1 to be electrically connected to the second end portions EP2 of the first light emitting elements LD1. The second connection electrode ELT2 may be provided on the second area (for example, the lower end area) of the first electrode ALE1 and the first end portions EP1 of the second light emitting elements LD2 to be electrically connected to the first end portions EP1 of the second light emitting elements LD2. For example, the second connection electrode ELT2 may electrically connect the second end portions EP2 of the first light emitting elements LD1 and the first end portions EP1 of the second light emitting elements LD2 in the light emitting area EA. For this, the second connection electrode ELT2 may have a curved shape. For example, the second connection electrode ELT2 may have a curved or bent structure at a boundary between an area in which at least one first light emitting element LD1 is arranged and an area in which at least one second light emitting element LD2 is arranged.

The third connection electrode ELT3 may be provided on the second area (for example, the lower end area) of the second electrode ALE2 and the second end portions EP2 of the second light emitting elements LD2 to be electrically connected to the second end portions EP2 of the second light emitting elements LD2. The third connection electrode ELT3 may be provided on the second area (for example, the lower end area) of the third electrode ALE3 and the first end portions EP1 of the third light emitting elements LD3 to be electrically connected to the first end portions EP1 of the third light emitting elements LD3. For example, the third connection electrode ELT3 may electrically connect the second end portions EP2 of the second light emitting elements LD2 and the first end portions EP1 of the third light emitting elements LD3 in the light emitting area EA. For this, the third connection electrode ELT3 may have a curved shape. For example, the third connection electrode ELT3 may have a curved or bent structure at a boundary between an area in which at least one second light emitting element LD2 is arranged and an area in which at least one third light emitting element LD3 is arranged.

The fourth connection electrode ELT4 may be provided on the second area (for example, the lower area) of the second electrode ALE2 and the second end portions EP2 of the third light emitting elements LD3 to be electrically connected to the second end portions EP2 of the third light emitting elements LD3. The fourth connection electrode ELT4 may be provided on the first area (for example, the upper end area) of the third electrode ALE3 and the first end portions EP1 of the fourth light emitting elements LD4 to be electrically connected to the first end portions EP1 of the fourth light emitting elements LD4. For example, the fourth connection electrode ELT4 may electrically connect the second end portions EP2 of the third light emitting elements LD3 and the first end portions EP1 of the fourth light emitting elements LD4 in the light emitting area EA. For this, the fourth connection electrode ELT4 may have a curved shape. For example, the fourth connection electrode ELT4 may have a curved or bent structure at a boundary between an area in which at least one third light emitting element LD3 is arranged and an area in which at least one fourth light emitting element LD4 is arranged.

The fifth connection electrode ELT5 may be provided on the first area (for example, the upper area) of the second electrode ALE2 and the second end portions EP2 of the fourth light emitting elements LD4 to be electrically connected to the second end portions EP2 of the fourth light emitting elements LD4.

The first connection electrode ELT1, the third connection electrode ELT3, and/or the fifth connection electrode ELT5 may be formed of the same conductive layer as each other. The second connection electrode ELT2 and the fourth connection electrode ELT4 may be formed of the same conductive layer as each other. For example, as shown in FIG. 5, the connection electrodes ELT may include a plurality of conductive layers. For example, the first connection electrode ELT1, the third connection electrode ELT3, and/or the fifth connection electrode ELT5 may be formed of the first conductive layer, and the second connection electrode ELT2 and the fourth connection electrode ELT4 may be formed of a second conductive layer different from the first conductive layer. In some embodiments, as shown in FIG. 7, the first to fifth connection electrodes ELT1, ELT2, ELT3, ELT4, and ELT5 may be formed of the same conductive layer as each other.

According to the present embodiments, the light emitting elements LD arranged between the electrodes ALE may be connected in a desired shape by using the connection electrodes ELT. For example, the first light emitting elements LD1, the second light emitting elements LD2, the third light emitting elements LD3, and the fourth light emitting elements LD4 may be sequentially connected in series by using the connection electrodes ELT.

Hereinafter, a cross-sectional structure of the pixel PXL will be described in more detail with reference to FIG. 8 to FIG. 12. FIG. 8 and FIG. 11 illustrate the first transistor M1 among one or more suitable circuit elements configuring the pixel circuit (PXC in FIG. 4), and when it is not necessary to separately denote the first to third transistors M1, M2, and M3, they will be comprehensively referred to a “transistor M”. However, structures of the transistors M and/or a position of each layer thereof are not limited to the embodiments shown in FIG. 8 and FIG. 11, and may be variously suitably changed according to the present embodiments.

The pixels PXL according to the embodiments may include circuit elements including the transistors M provided on the base layer BSL and one or more suitable wires connected thereto. The electrodes ALE, the light emitting elements LD, the connection electrodes ELT, the first bank BNK1, and/or the second bank BNK2 configuring the light emitting part EMU may be provided on the circuit elements.

The base layer BSL configures a base member, and may be a rigid or flexible substrate and/or film. For example, the base layer BSL may be a hard substrate made of glass or tempered glass, a flexible substrate (or a thin film) made of a plastic and/or metallic material, or at least one layered insulation layer. The material and/or physical properties of the base layer BSL are not particularly limited. In the embodiments, the base layer BSL may be substantially transparent. Here, the “substantially transparent” may mean that light may be transmitted at a set or predetermined transmittance or more. In some embodiments, the base layer BSL may be translucent or opaque. In some embodiments, the base layer BSL may include a reflective material.

The lower conductive layer BML and a first power conductive layer PL2a may be provided on the base layer BSL. The lower conductive layer BML and the first power conductive layer PL2a may be provided on the same layer. For example, the lower conductive layer BML and the first power conductive layer PL2a may be simultaneously (or concurrently) formed in the same process, but the present disclosure is not limited thereto. The first power conductive layer PL2a may configure the second power line PL2 described with reference to FIG. 4 and/or the like.

Each of the lower conductive layer BML and the first power conductive layer PL2a may be formed as a single layer or multilayer made of molybdenum (Mo), copper (Cu), aluminum (A1), chromium (Cr), gold (Au), titanium (Ti), nickel (Ni), neodymium (Nd), indium (In), tin (Sn), an oxide thereof, and/or an alloy thereof.

A buffer layer BFL may be provided on the lower conductive layer BML and the first power conductive layer PL2a. The buffer layer BFL may prevent or reduce the diffusion of impurities into the circuit element. The buffer layer BFL may be formed as a single layer, but may also be formed as a multilayer of at least double layers or more. When the buffer layer BFL is formed as the multilayer, respective layers may be made of the same material or different materials.

A semiconductor pattern SCP may be provided on the buffer layer BFL. For example, the semiconductor pattern SCP may include a first area contacting a first transistor electrode TE1, a second area contacting a second transistor electrode TE2, and a channel area provided between the first and second areas. In some embodiments, one selected from among the first and second areas may be a source area, and the other thereof may be a drain area.

In some embodiments, the semiconductor pattern SCP may be made of polysilicon, amorphous silicon, an oxide semiconductor, and/or the like. The channel area of the semiconductor pattern SCP may be an intrinsic semiconductor as a semiconductor pattern that is not doped with impurities, and each of the first and second areas of the semiconductor pattern SCP may be a semiconductor doped with set or predetermined impurities.

A gate insulation layer GI may be provided on the buffer layer BFL and the semiconductor pattern SCP. For example, the gate insulation layer GI may be provided between the semiconductor pattern SCP and the gate electrode GE. The gate insulation layer GI may be provided between the buffer layer BFL and a second power conductive layer PL2b. The gate insulation layer GI may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The gate electrode GE of the transistor M and the second power conductive layer PL2b may be provided on the gate insulation layer GI. The gate electrode GE and the second power conductive layer PL2b may be provided on the same layer. For example, the gate electrode GE and the second power conductive layer PL2b may be simultaneously (or concurrently) formed in the same process, but the present disclosure is not limited thereto. The gate electrode GE may be provided to overlap the semiconductor pattern SCP in a third direction (a Z-axis direction) on the gate insulation layer GI. The second power conductive layer PL2b may be provided to overlap the first power conductive layer PL2a on the gate insulation layer GI in the third direction (Z-axis direction). The second power conductive layer PL2b together with the first power conductive layer PL2a may configure the second power line PL2 described with reference to FIG. 4 and/or the like.

Each of the gate electrode GE and the second power conductive layer PL2b may be formed as a single layer or multilayer made of molybdenum (Mo), copper (Cu), aluminum (Al), chromium (Cr), gold (Au), titanium (Ti), nickel (Ni), neodymium (Nd), indium (In), tin (Sn), an oxide thereof, and/or an alloy thereof. For example, each of the gate electrode GE and the second power conductive layer PL2b may be formed as a multilayer in which titanium (Ti), copper (Cu), and/or an indium tin oxide (ITO) are sequentially or repeatedly stacked.

An interlayer insulation layer ILD may be provided on the gate electrode GE and the second power conductive layer PL2b. For example, the interlayer insulation layer ILD may be provided between the gate electrode GE and the first and second transistor electrodes TE1 and TE2. The interlayer insulation layer ILD may be provided between the second power conductive layer PL2b and a third power conductive layer PL2c.

The interlayer insulation layer ILD may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The first and second transistor electrodes TE1 and TE2 of the transistor M and the third power conductive layer PL2c may be provided on the interlayer insulation layer ILD. The first and second transistor electrodes TE1 and TE2 and the third power conductive layer PL2c may be provided on the same layer. For example, the first and second transistor electrodes TE1 and TE2 and the third power conductive layer PL2c may be simultaneously (or concurrently) formed in the same process, but are not limited thereto.

The first and second transistor electrodes TE1 and TE2 may be provided to overlap the semiconductor pattern SCP in the third direction (Z-axis direction). The first and second transistor electrodes TE1 and TE2 may be electrically connected to the semiconductor pattern SCP. For example, the first transistor electrode TE1 may be electrically connected to the first area of the semiconductor pattern SCP through a contact hole penetrating the interlayer insulation layer ILD. The first transistor electrode TE1 may be electrically connected to the lower conductive layer BML through a contact hole penetrating the interlayer insulation layer ILD and the buffer layer BFL. The second transistor electrode TE2 may be electrically connected to the second area of the semiconductor pattern SCP through a contact hole penetrating the interlayer insulation layer ILD. In some embodiments, one selected from among the first and second transistor electrodes TE1 and TE2 may be a source electrode, and the other thereof may be a drain electrode.

The third power conductive layer PL2c may be provided to overlap the first power conductive layer PL2a and/or the second power conductive layer PL2b in the third direction (Z-axis direction). The third power conductive layer PL2c may be electrically connected to the first power conductive layer PL2a and/or the second power conductive layer PL2b. For example, the third power conductive layer PL2c may be electrically connected to the first power conductive layer PL2a through a contact hole penetrating the interlayer insulation layer ILD and the buffer layer BFL. The third power conductive layer PL2c may be electrically connected to the second power conductive layer PL2b through a contact hole penetrating the interlayer insulation layer ILD. The third power conductive layer PL2c together with the first power conductive layer PL2a and/or the second power conductive layer PL2b may configure the second power line PL2 described with reference to FIG. 4 and/or the like.

The first and second transistor electrodes TE1 and TE2 and the third power conductive layer PL2c may be formed as a single layer or multilayer made of molybdenum (Mo), copper (Cu), aluminum (A1), chromium (Cr), gold (Au), titanium (Ti), nickel (Ni), neodymium (Nd), indium (In), tin (Sn), an oxide thereof, and/or an alloy thereof.

A passivation layer PSV may be provided on the first and second transistor electrodes TE1 and TE2 and the third power conductive layer PL2c. The passivation layer PSV may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

A via layer VIA may be provided on the passivation layer PSV. The via layer VIA may be made of an organic material to flatten or reduce a lower step thereof. For example, the via layer VIA may include an organic material such as an acrylate resin, an epoxy resin, a phenolic resin, a polyamide resin, a polyimide resin, a polyester resin, a polyphenylenesulfide resin, and/or a benzocyclobutene (BCB). However, it is not necessarily limited thereto, and the via layer VIA may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The partition walls WL may be provided on the via layer VIA. The partition walls WL may serve to form a set or predetermined step so as to easily align the light emitting elements LD in the light emitting area EA.

In some embodiments, the partition walls WL may have one or more suitable shapes. In the embodiments, the partition walls WL may have a shape protruding in the third direction (Z-axis direction) on the base layer BSL. The partition walls WL may be formed to have an inclined surface inclined at a set or predetermined angle with respect to the base layer BSL. However, the present disclosure is not necessarily limited thereto, and the partition walls WL may have a side wall having a curved surface or a step (e.g., stepped) shape. For example, the partition walls WL may have a cross-section of a semicircular or semi-elliptical shape.

The partition walls WL may include at least one organic material and/or inorganic material. For example, the partition walls WL may include an organic material such as an acrylate resin, an epoxy resin, a phenolic resin, a polyamide resin, a polyimide resin, a polyester resin, a polyphenylenesulfide resin, and/or a benzocyclobutene (BCB). However, it is not necessarily limited thereto, and the partition walls WL may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The electrodes ALE may be provided on the via layer VIA and the partition walls WL. The electrodes ALE may at least partially cover side surfaces and/or upper surfaces of the partition walls WL. The electrodes ALE provided on the partition walls WL may have shapes corresponding to the respective partition walls WL. For example, the electrodes ALE provided on the partition walls WL may include inclined surfaces or curved surfaces having shapes corresponding to the shapes of the respective partition walls WL. In this case, the partition walls WL and the electrodes ALE are reflective members and may reflect light emitted from the light emitting elements LD to guide it in the front surface direction of the pixel PXL, that is, in the third direction (Z-axis direction), so that the light output efficiency of the display panel PNL may be improved.

The electrodes ALE may be provided to be spaced apart from each other. The electrodes ALE may be provided on the same layer. For example, the electrodes ALE may be simultaneously (or concurrently) formed in the same process, but is not limited thereto.

The electrodes ALE may receive an alignment signal in the alignment step of the light emitting elements LD. Accordingly, an electric field is formed between the electrodes ALE so that the light emitting elements LD provided to each pixel PXL may be deflectively aligned between the electrodes ALE.

The electrodes ALE may include at least one conductive material. For example, the electrodes ALE may include at least one metal of one or more suitable metal materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and/or an alloy including the same; a conductive oxide such as an indium tin oxide (ITO), an indium zinc oxide (IZO), an indium tin zinc Oxide (ITZO), an aluminum zinc oxide (AZO), a gallium zinc oxide (GZO), a zinc tin oxide (ZTO), and/or a gallium tin oxide (GTO); and at least one conductive material selected from among conductive polymers such as PEDOT, but are not necessarily limited thereto.

The first electrode ALE1 may be electrically connected to the first transistor electrode TE1 of the transistor M through a contact hole penetrating the via layer VIA and the passivation layer PSV. The second electrode ALE2 may be electrically connected to the third power conductive layer PL2c through a contact hole penetrating the via layer VIA and the passivation layer PSV.

The first insulation layer INS1 may be provided on electrodes ALE. The first insulation layer INS1 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

Referring to FIG. 10, the hole HL may be formed in the electrodes ALE and the first insulation layer INS1. The hole HL may pass through the electrodes ALE and the first insulation layer INS1 to expose the partition wall WL provided thereunder. The first bank BNK1 provided on the first insulation layer INS1 may contact the partition wall WL through the hole HL. FIG. 10 illustrates a cross-sectional view of the hole HL centered on the first hole HL1, and the first to third holes HL1, HL2, and HL3 may have the same cross-sectional structure. For example, the first holes HL1 of the electrodes ALE and the first insulation layer INS1 may overlap each other in the third direction (Z-axis direction). The second holes HL2 of the electrodes ALE and the first insulation layer INS1 may overlap each other in the third direction (Z-axis direction). The third holes HL3 of the electrodes ALE and the first insulation layer INS1 may overlap each other in the third direction (Z-axis direction).

In some embodiments, the partition wall WL may be partially etched in the process of forming the hole HL by etching the electrodes ALE and the first insulation layer INS1. Accordingly, a recessed portion WLR may be formed in the partition wall WL. For example, the recessed portion WLR may overlap the hole HL and may be simultaneously (or concurrently) formed. The first bank BNK1 may be provided in the recessed portion WLR. The first bank BNK1 may be formed flat (or substantially flat) by leveling or reducing a step generated by the recessed portion WLR. In some embodiments, a step may be formed as the first bank BNK1 is provided in the recessed portion WLR. For example, the first bank BNK1 may be partially recessed on the recessed portion WLR. A recessed depth of the first bank BNK1 may be smaller than a depth of the recessed portion WLR formed in the partition wall WL, but is not necessarily limited thereto.

As described above, when the hole HL is formed in the electrodes ALE and the first insulation layer INS1, even if outgas occurs from the via layer VIA and/or the partition wall WL made of the organic material during the manufacturing process of the display device, the outgas may be released through the hole HL formed in the electrodes ALE and the first insulation layer INS1, so that defects caused by the outgas may be minimized or reduced.

The first bank BNK1 may be provided on the first insulation layer INS1. The first bank BNK1 may surround the light emitting area EA. The opening of the first bank BNK1 may provide a space in which the light emitting elements LD may be provided in a step of supplying the light emitting elements LD to each of the pixels PXL. For example, a desired type (or kind) and/or amount of light emitting element ink may be supplied to a space partitioned by the opening of the first bank BNK1.

The first bank BNK1 may include an organic material such as an acrylate resin, an epoxy resin, a phenolic resin, a polyamide resin, a polyimide resin, a polyester resin, a polyphenylenesulfide resin, and/or a benzocyclobutene (BCB). However, it is not necessarily limited thereto, and the first bank BNK1 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The light emitting elements LD may be provided between the electrodes ALE. The light emitting elements LD may be provided within the opening of the first bank BNK1 to be provided between the partition walls WL.

The light emitting elements LD may be prepared in a form dispersed in light emitting element ink, and may be supplied to each pixel PXL through an inkjet printing method and/or the like. For example, the light emitting elements LD may be dispersed in a volatile solvent to be provided in each pixel PXL. Subsequently, when an alignment signal is supplied to the electrodes ALE, an electric field is formed between the electrodes ALE, so that the light emitting elements LD may be aligned between the electrodes ALE. After the light emitting elements LD are aligned, the light emitting elements LD may be stably or suitably arranged between the electrodes ALE by volatilizing the solvent or eliminating it in other suitable ways.

A second insulation layer INS2 may be provided on the light emitting elements LD. For example, the second insulation layer INS2 is partially provided on the light emitting elements LD, and may expose the first and second end portions EP1 and EP2 of the light emitting elements LD. When the second insulation layer INS2 is formed on the light emitting elements LD after the alignment of the light emitting elements LD is completed, it is possible to prevent or reduce the deviation of the light emitting elements LD from an aligned position.

The second insulation layer INS2 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The connection electrodes ELT may be provided on the first and second end portions EP1 and EP2 of the light emitting elements LD exposed by the second insulation layer INS2. The first connection electrode ELT1 may be directly provided on the first end portions EP1 of the first light emitting elements LD1 to contact the first end portions EP1 of the first light emitting elements LD1.

The second connection electrode ELT2 may be directly provided on the second end portions EP2 of the first light emitting elements LD1 to contact the second end portions EP2 of the first light emitting elements LD1. The second connection electrode ELT2 may be directly provided on the first end portions EP1 of the second light emitting elements LD2 to contact the first end portions EP1 of the second light emitting elements LD2. For example, the second connection electrode ELT2 may electrically connect the second end portions EP2 of the first light emitting elements LD1 and the first end portions EP1 of the second light emitting elements LD2.

In one or more embodiments, the third connection electrode ELT3 may be directly provided on the second end portions EP2 of the second light emitting elements LD2 to contact the second end portions EP2 of the second light emitting elements LD2. The third connection electrode ELT3 may be directly provided on the first end portions EP1 of the third light emitting elements LD3 to contact the first end portions EP1 of the third light emitting elements LD3. For example, the third connection electrode ELT3 may electrically connect the second end portions EP2 of the second light emitting elements LD2 and the first end portions EP1 of the third light emitting elements LD3.

The fourth connection electrode ELT4 may be directly provided on the second end portions EP2 of the third light emitting elements LD3 to contact the second end portions EP2 of the third light emitting elements LD3. The fourth connection electrode ELT4 may be directly provided on the first end portions EP1 of the fourth light emitting elements LD4 to contact the first end portions EP1 of the fourth light emitting elements LD4. For example, the fourth connection electrode ELT4 may electrically connect the second end portions EP2 of the third light emitting elements LD3 and the first end portions EP1 of the fourth light emitting elements LD4.

The fifth connection electrode ELT5 may be directly provided on the second end portions EP2 of the fourth light emitting elements LD4 to contact the second end portions EP2 of the fourth light emitting elements LD4.

The first connection electrode ELT1 may be electrically connected to the first electrode ALE1 through a contact hole penetrating the first insulation layer INS1. The fifth connection electrode ELT5 may be electrically connected to the second electrode ALE2 through a contact hole penetrating the first insulation layer INS1.

In the embodiments, the connection electrodes ELT may be configured of a plurality of conductive layers. For example, as shown in FIG. 6, FIG. 8, and FIG. 9, the first connection electrode ELT1, the third connection electrode ELT3, and the fifth connection electrode ELT5 may be provided on the same layer. The second connection electrode ELT2 and the fourth connection electrode ELT4 may be provided on the same layer. The first connection electrode ELT1, the third connection electrode ELT3, and the fifth connection electrode ELT5 may be provided on the second insulation layer INS2. A third insulation layer INS3 may be provided on the first connection electrode ELT1, the third connection electrode ELT3, and the fifth connection electrode ELT5. The second connection electrode ELT2 and the fourth connection electrode ELT4 may be provided on the third insulation layer INS3. As described above, when the third insulation layer INS3 is provided between the connection electrodes ELT made of (or on) different conductive layers, because the connection electrodes ELT may be stably or suitably separated by the third insulation layer INS3, it is possible to ensure (or improve) electrical stability between the first and second end portions EP1 and EP2 of the light emitting elements LD.

The third insulation layer INS3 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

In one or more embodiments, the connection electrodes ELT may be configured of the same conductive layer as each other. For example, as shown in FIG. 7, FIG. 11, and FIG. 12, the first to fifth connection electrodes ELT1, ELT2, ELT3, ELT4, and ELT5 may be provided on the same layer. For example, the first to fifth connection electrodes ELT1, ELT2, ELT3, ELT4, and ELT5 may be simultaneously (or concurrently) formed in the same process. As described above, when the connection electrodes ELT are simultaneously (or concurrently) formed, the number of masks may be reduced, and the manufacturing process may be simplified.

The connection electrodes ELT may be made of one or more suitable transparent conductive materials. For example, the connection electrodes ELT may include at least one selected from among one or more suitable transparent conductive materials including an indium tin oxide (ITO), an indium zinc oxide (IZO), an indium tin zinc oxide (ITZO), an aluminum zinc oxide (AZO), a gallium zinc oxide (GZO), a zinc tin oxide (ZTO), and a gallium tin oxide (GTO), and may be realized to be substantially transparent or translucent to satisfy a set or predetermined light transmittance. Accordingly, the light emitted from the first and second end portions EP1 and EP2 of the light emitting elements LD may pass through the connection electrodes ELT to be emitted to the outside of the display panel PNL.

The second bank BNK2 may be provided on first bank BNK1. The second bank BNK2 may be provided in the non-light emitting area NEA. The second bank BNK2 may overlap the hole HL described above, but is not necessarily limited thereto.

The second bank BNK2 may surround the light emitting area EA. The second bank BNK2 may include an opening overlapping the light emitting area EA. The opening of the second bank BNK2 may provide a space in which a color conversion layer to be described in more detail hereinbelow may be provided. For example, a desired type (or kind) and/or amount of the color conversion layer may be supplied to a space partitioned by the opening of the second bank BNK2.

The second bank BNK2 may include an organic material such as an acrylate resin, an epoxy resin, a phenolic resin, a polyamide resin, a polyimide resin, a polyester resin, a polyphenylenesulfide resin, and/or a benzocyclobutene (BCB). However, it is not necessarily limited thereto, and the second bank BNK2 may be configured as a single layer or multilayer, and may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

In some embodiments, the second bank BNK2 may include at least one light blocking and/or reflective material. Accordingly, light leakage between adjacent pixels PXL may be prevented or reduced. For example, the second bank BNK2 may include at least one black pigment.

According to the above embodiment, by forming the holes HL of different shapes between respective pixels PXL, it is possible to prevent or reduce defects due to outgas, and simultaneously (or concurrently), to increase repair productivity by distinguishing the first to third pixels PXL1, PXL2, and PXL3.

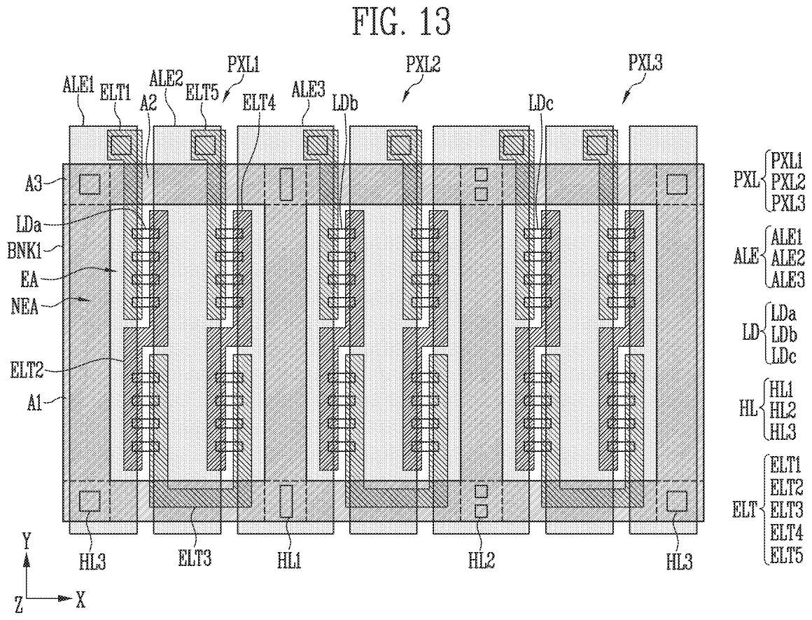

FIG. 13 illustrates a top plan view of first to third pixels according to one or more embodiments.

Referring to FIG. 13, the hole HL may be provided in a crossing portion A3 in which the first area A1 and the second area A2 of the first bank BNK1 cross. The first hole HL1 may be positioned in a crossing portion A3 between the first pixel PXL1 and the second pixel PXL2, the second hole HL2 may be positioned in a crossing portion A3 between the second pixel PXL2 and the third pixel PXL3, and the third hole HL3 may be positioned in a crossing portion A3 between the third pixel PXL3 and the first pixel PXL1.

The first hole HL1 may overlap the crossing portion A3 of the first bank BNK1 at one side of the second pixel PXL2 (or the other side of the first pixel PXL1), the second hole HL2 may overlap the crossing portion A3 of the first bank BNK1 at the other side of the second pixel PXL2 (or one side of the third pixel PXL3), and the third hole HL3 may overlap the crossing portion A3 of the first bank BNK1 at the other side of the third pixel PXL3 (or one side of the first pixel PXL1).

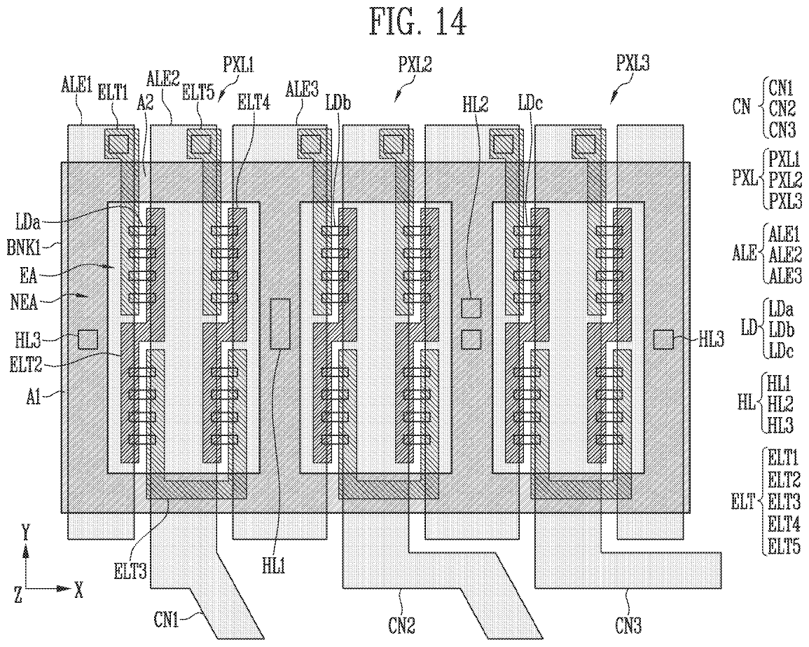

FIG. 14 illustrates a top plan view of first to third pixels according to one or more embodiments.

Referring to FIG. 14, the electrodes ALE may include a connection portion CN positioned outside the first bank BNK1. The connection portion CN may electrically connect the electrodes ALE of adjacent pixels PXL in the second direction (Y-axis direction). At least one of the electrodes ALE of the first pixel PXL1 may include a first connection portion CN1. At least one of the electrodes ALE of the second pixel PXL2 may include a second connection portion CN2. At least one of the electrodes ALE of the third pixel PXL3 may include a third connection part CN3.

The first to third connection portions CN1, CN2, and CN3 may be formed to have different shapes. For example, as shown in FIG. 14, the first connection portion CN1 may have an inclined shape, the second connection portion CN2 may have an area extending in the first direction (X-axis direction) and an inclined area, and the third connection portion CN3 may have a shape extending in the first direction (X-axis direction). However, the first to third connection portions CN1, CN2, and CN3 are not limited to those illustrated in FIG. 14, and may be variously suitably changed within a range in which the shapes of the first to third connectors CN1, CN2, and CN3 may be distinguished. As described above, the first to third pixels PXL1, PXL2, and PXL3 are differentiated by differently forming the shapes, areas, and/or numbers of connection portions CN of the electrodes ALE of each of the pixels PXL, so that the productivity may be increased by repair-printing the light emitting elements LD for each PXL.

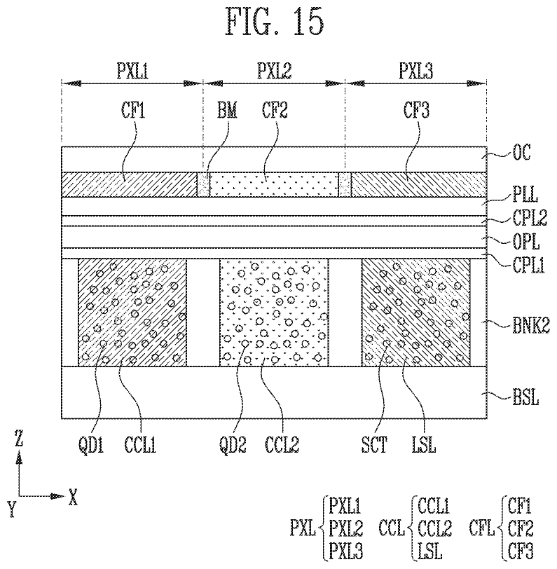

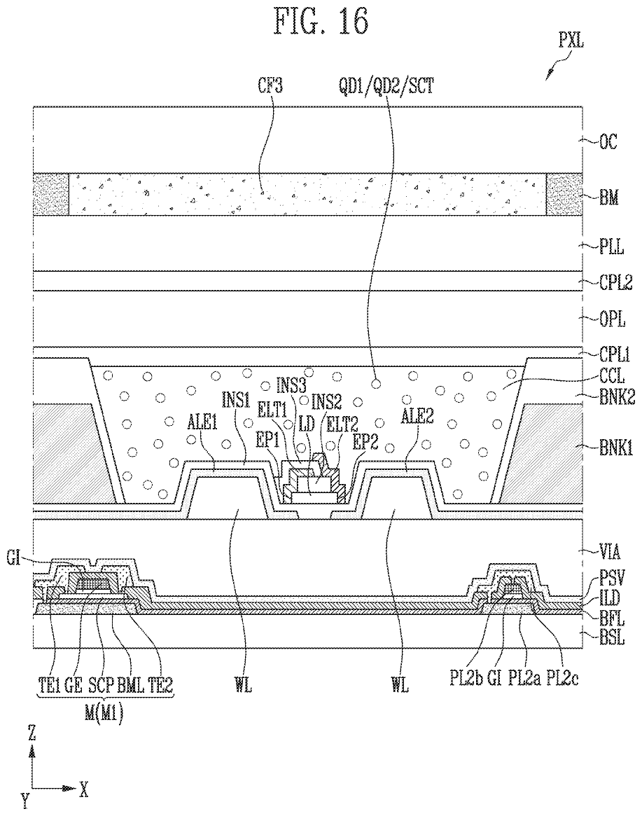

FIG. 15 illustrates a cross-sectional view of first to third pixels according to one or more embodiments. FIG. 16 illustrates a cross-sectional view of a pixel according to one or more embodiments.

FIG. 15 illustrates a color conversion layer CCL, an optical layer OPL, and/or a color filter layer CFL. In FIG. 15, components of FIG. 8 to FIG. 12, except for the base layer BSL and the second bank BNK2, are omitted (are not provided) for better understanding and ease of description. FIG. 16 illustrates a stacked structure of the pixel PXL in relation to the color conversion layer CCL, the optical layer OPL, and/or the color filter layer CFL.

Referring to FIG. 15 and FIG. 16, the second bank BNK2 is provided between the first to third pixels PXL1, PXL2, and PXL3 or at a boundary thereof, and may include an opening respectively overlapping the first to third pixels PXL1, PXL2, and PXL3. The opening of the second bank BNK2 may provide a space in which the color conversion layer CCL may be provided.

The color conversion layer CCL may be provided on the light emitting elements LD in an opening of the second bank BNK2. The color conversion layer CCL may include a first color conversion layer CCL1 provided on the first pixel PXL1, a second color conversion layer CCL2 provided on the second pixel PXL2, and a scattering layer LSL provided on the third pixel PXL3.

The first color conversion layer CCL1 may include first color conversion particles that may convert light of the third color emitted from the light emitting element LD into light of the first color. For example, the first color conversion layer CCL1 may include a plurality of first quantum dots QD1 dispersed in a set or predetermined matrix material such as a base resin.

In the embodiments, when the light emitting element LD is a blue light emitting element that emits blue light and the first pixel PXL1 is a red pixel, the first color conversion layer CCL1 may include a first quantum dot QD1 that converts blue light emitted from the blue light emitting element into red light. The first quantum dot QD1 may absorb blue light to shift a wavelength according to an energy transition to emit red light. When the first pixel PXL1 is a pixel of a different color, the first color conversion layer CCL1 may include a first quantum dot QD1 corresponding to a color of the first pixel PXL1.

The second color conversion layer CCL2 may include second color conversion particles that may convert light of the third color emitted from the light emitting element LD into light of the second color. For example, the second color conversion layer CCL2 may include a plurality of second quantum dots QD2 dispersed in a set or predetermined matrix material such as a base resin.

In the embodiments, when the light emitting element LD is a blue light emitting element that emits blue light and the second pixel PXL2 is a green pixel, the second color conversion layer CCL2 may include a second quantum dot QD2 that converts blue light emitted from the blue light emitting element into green light. The second quantum dot QD2 may absorb blue light to shift a wavelength according to an energy transition to emit green light. When the second pixel PXL2 is a pixel of a different color, the second color conversion layer CCL2 may include the second quantum dot QD2 corresponding to a color of the second pixel PXL2.

In the embodiments, blue light having a relatively short wavelength among the visible ray bands is incident on the first quantum dot QD1 and the second quantum dot QD2, respectively, thereby increasing absorption coefficient of the first quantum dot QD1 and the second quantum dot QD2. Accordingly, the efficiency of light emitted from the first pixel PXL1 and the second pixel PXL2 may be finally increased (e.g., further increased), and at the same time, excellent or improved color reproducibility may be secured. The light emitting part EMU of the first to third pixels PXL1, PXL2, and PXL3 is configured by using the light emitting elements LD of the same color (for example, the blue color light emitting element), thereby increasing the manufacturing efficiency of the display device.

The scattering layer LSL may be provided to efficiently or suitable utilize the third color (or blue color) light emitted from the light emitting element LD. For example, when the light emitting element LD is a blue light emitting element that emits blue light and the third pixel PXL3 is a blue pixel, the scattering layer LSL may include at least one type (or kind) of scatterer SCT to efficiently or suitably use (e.g., transmit) the light emitted from the light emitting element LD. For example, the scatterer SCT of the scattering layer LSL may include at least one selected from among a barium sulfate (BaSO₄), a calcium carbonate (CaCO₃), a titanium oxide (TiO₂), a silicon oxide (SiO₂), an aluminum oxide (Al₂O₃), a zirconium oxide (ZrO₂), and a zinc oxide (ZnO). In one or more embodiments, the scatterer SCT is not provided only in the third pixel PXL3, and may be selectively included in the first color conversion layer CCL1 and/or the second color conversion layer CCL2. In some embodiments, the scatterer SCT may not be provided (e.g., may be omitted) and the scattering layer LSL may be made of a transparent polymer.

A first capping layer CPL1 may be provided on the color conversion layer CCL. The first capping layer CPL1 may be entirely provided on the first to third pixels PXL1, PXL2, and PXL3. The first capping layer CPL1 may cover the color conversion layer CCL. The first capping layer CPL1 may prevent or reduce impurities such as moisture and/or air from penetrating from the outside to damage and/or contaminate the color conversion layer CCL.

The first capping layer CPL1 is an inorganic layer, which may include a silicon nitride (SiNx), an aluminum nitride (AlNx), a titanium nitride (TiNx), a silicon oxide (SiOx), an aluminum oxide (AlOx), a titanium oxide (TiOx), a silicon oxycarbide (SiOxCy), and/or a silicon oxynitride (SiOxNy).

The optical layer OPL may be provided on the first capping layer CPL1. The optical layer OPL may serve to improve light extraction efficiency by recycling light provided from the color conversion layer CCL by total reflection. To this end, the optical layer OPL may have a relatively low refractive index compared to the color conversion layer CCL. For example, the refractive index of the color conversion layer CCL may be about 1.6 to 2.0, and the refractive index of the optical layer OPL may be about 1.1 to 1.3.

A second capping layer CPL2 may be provided on the optical layer OPL. The second capping layer CPL2 may be entirely provided on the first to third pixels PXL1, PXL2, and PXL3. The second capping layer CPL2 may cover the optical layer OPL. The second capping layer CPL2 may prevent or reduce the penetration of impurities such as moisture and/or from the outside to damage and/or contaminate the optical layer OPL.

The second capping layer CPL2 is an inorganic layer, which may include a silicon nitride (SiNx), an aluminum nitride (AlNx), a titanium nitride (TiNx), a silicon oxide (SiOx), an aluminum oxide (AlOx), a titanium oxide (TiOx), a silicon oxycarbide (SiOxCy), and/or a silicon oxynitride (SiOxNy).

A planarization layer PLL may be provided on the second capping layer CPL2. The planarization layer PLL may be entirely provided in the first to third pixels PXL1, PXL2, and PXL3.

The planarization layer PLL may include an organic material such as an acrylic resin, an epoxy resin, a phenolic resin, a polyamide resin, a polyimide rein, a polyester resin, a polyphenylenesulfide resin, and/or a benzocyclobutene (BCB). However, it is not necessarily limited thereto, and the planarization layer PLL may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

The color filter layer CFL may be provided on the planarization layer PLL. The color filter layer CFL may include color filters CF1, CF2, and CF3 respectively matching the color of each pixel PXL. A full-color image may be displayed by providing the color filters CF1, CF2, and CF3 matching respective colors of the first to third pixels PXL1, PXL2, and PXL3.

The color filter layer CFL may include a first color filter CF1 that is provided in the first pixel PXL1 to selectively transmit light emitted by the first pixel PXL1, a second color filter CF2 that is provided in the second pixel PXL2 to selectively transmit light emitted by the second pixel PXL2, and a third color filter CF3 that is provided in the third pixel PXL3 to selectively transmit light emitted by the third pixel PXL3.

In the embodiments, the first color filter CF1, the second color filter CF2, and the third color filter CF3 may be a red color filter, a green color filter, and a blue color filter, respectively, but the present disclosure is not limited necessarily thereto. Hereinafter, when referring to one selected from among the first color filter CF1, the second color filter CF2, and the third color filter CF3, or when comprehensively referring to two or more thereof, it will be referred to as the “color filter CF” or “color filters CF”.

The first color filter CF1 may overlap the first color conversion layer CCL1 in the third direction (Z-axis direction). The first color filter CF1 may include a color filter material that selectively transmits light of a first color (or red color). For example, when the first pixel PXL1 is a red pixel, the first color filter CF1 may include a red color filter material.

The second color filter CF2 may overlap the second color conversion layer CCL2 in the third direction (Z-axis direction). The second color filter CF2 may include a color filter material that selectively transmits light of a second color (or green color). For example, when the second pixel PXL2 is a green pixel, the second color filter CF2 may include a green color filter material.

The third color filter CF3 may overlap the scattering layer LSL in the third direction (Z-axis direction). The third color filter CF3 may include a color filter material that selectively transmits light of a third color (or blue color). For example, when the third pixel PXL3 is a blue pixel, the third color filter CF3 may include a blue color filter material.

In some embodiments, a light blocking layer BM may be further provided between the first to third color filters CF1, CF2, and CF3, and in this case, when the light blocking layer BM is formed between the first to third color filters CF1, CF2, and CF3, it is possible to prevent or reduce a color mixing defect viewed (that may otherwise be seen) from a front or side of a display device. A material of a light blocking layer BM is not particularly limited, and may be made of one or more suitable light blocking materials. For example, the light blocking layer BM may be implemented by stacking the first to third color filters CF1, CF2, and CF3 on each other.

An overcoat layer OC may be provided on the color filter layer CFL. The overcoat layer OC may be entirely (e.g., commonly) provided in the first to third pixels PXL1, PXL2, and PXL3. The overcoat layer OC may cover the color filter layer CFL and a lower member thereof. The overcoat layer OC may prevent or reduce the penetration of moisture and/or air into the above-mentioned lower members that are provided therebelow. The overcoat layer OC may protect the above-mentioned lower members from foreign matters such as dust.

The overcoat layer OC may include an organic material such as an acrylic resin, an epoxy resin, a phenolic resin, a polyamide resin, a polyimide rein, a polyester resin, a polyphenylenesulfide resin, and/or a benzocyclobutene (BCB). However, it is not necessarily limited thereto, and the overcoat layer OC may include a silicon oxide (SiOx), a silicon nitride (SiNx), a silicon oxynitride (SiOxNy), an aluminum nitride (AlNx), an aluminum oxide (AlOx), a zirconium oxide (ZrOx), a hafnium oxide (HfOx), a titanium oxide (TiOx), and/or one or more suitable types (or kinds) of inorganic materials.

Those skilled in the art related to the present embodiments will readily appreciate that many modifications are possible without materially departing from the scope of the present disclosure. The embodiments should be considered in a descriptive sense only and not for purposes of limitation. The scope of the present disclosure will be defined by the detailed description and the appended claims, and all differences within the equivalent scope will be construed as being included in the present disclosure.

What is claimed is:

1. A display device comprising:
electrodes spaced apart from each other in a pixel;
a bank on the electrodes and around a light emitting area of the pixel; and
light emitting elements between the electrodes in the light emitting area,
wherein the electrodes comprise a first hole overlapping the bank at one side of the pixel, and a second hole overlapping the bank at another side of the pixel, and
a shape of the first hole of the electrodes is different from a shape of the second hole of the electrodes.

2. The display device of claim 1, further comprising
an insulation layer between the electrodes and the light emitting elements.

3. The display device of claim 2, wherein
the insulation layer is between the electrodes and the bank.

4. The display device of claim 2, wherein
the insulation layer comprises a first hole overlapping the bank at the one side of the pixel, and a second hole overlapping the bank at the other side of the pixel.

5. The display device of claim 4, wherein
the first hole of the insulation layer overlaps the first hole of the electrodes, and
the second hole of the insulation layer overlaps the second hole of the electrodes.

6. The display device of claim 1, further comprising
a partition wall below the electrodes.

7. The display device of claim 6, wherein
the bank contacts the partition wall through the first hole of the electrodes and the second hole of the electrodes.

8. The display device of claim 6, wherein
the partition wall comprises a recessed portion overlapping the first hole of the electrodes and the second hole of the electrodes.

9. The display device of claim 1, wherein
the pixel comprises a first pixel, a second pixel, and a third pixel,
the first hole of the electrodes is between the first pixel and the second pixel, and
the second hole of the electrodes is between the second pixel and the third pixel.

10. The display device of claim 9, wherein
the electrodes further comprise a third hole between the third pixel and the first pixel.

11. The display device of claim 10, wherein
the light emitting elements comprise a first light emitting element, a second light emitting element, and a third light emitting element that are configured to emit light of different colors from the first pixel, the second pixel, and the third pixel, respectively.

12. A display device comprising:
electrodes spaced apart from each other in a pixel;
a bank on the electrodes and around a light emitting area of the pixel; and
light emitting elements between the electrodes in the light emitting area,
wherein the bank comprises first areas that extend in a first direction and are spaced apart from each other,
the electrodes comprise a first hole and a second hole overlapping the first areas, and
a shape of the first hole of the electrodes is different from a shape of the second hole of the electrodes.

13. The display device of claim 12, wherein
the bank further comprises second areas that extends in a second direction crossing the first direction and are spaced apart from each other.

14. The display device of claim 13, wherein
the first hole of the electrodes and the second hole of the electrodes do not overlap the second area.

15. The display device of claim 13, wherein
the electrodes comprise a connection portion outside of the bank.

16. The display device of claim 15, wherein
the pixel comprises a first pixel, a second pixel, and a third pixel arranged in the second direction, and
a shape of the connection portion of the electrodes of the first pixel is different from a shape of the connection portion of the electrodes of the second pixel.

17. The display device of claim 16, wherein
the light emitting elements comprise a first light emitting element, a second light emitting element, and a third light emitting element that are configured to emit light of different colors from the first pixel, the second pixel, and the third pixel, respectively.

18. The display device of claim 16, wherein
the first hole of the electrodes is between the first pixel and the second pixel, and
the second hole of the electrodes is between the second pixel and the third pixel.

19. The display device of claim 12, wherein
an area of the first hole of the electrodes is different from an area of the second hole of the electrodes.

20. The display device of claim 12, wherein
the first hole of the electrodes is a plurality of first holes of the electrodes, and the second hole of the electrodes is a plurality of second holes of the electrodes, and
a number of the plurality of first holes of the electrodes is different from a number of the plurality of second holes of the electrodes.
